(19) United States
(12) Patent Application Publication
(10) Pub. No.: US 2016/0379777 A1
(43) Pub. Date: Dec. 29, 2016

(54) OPERATION DEVICE

(71) Applicant: KABUSHIKI KAISHA TOKAI RIKA DENKI SEISAKUSHO, Aichi (JP)

(72) Inventors: Yoshiaki NABE, Aichi (JP); Takeyoshi MORI, Aichi (JP); Shinichi UEDA, Aichi (JP)

(21) Appl. No.: 15/103,224

(22) PCT Filed: Oct. 14, 2014
(86) PCT No.: PCT/JP2014/077344

§ 371 Date: Jun. 9, 2016

(30) Foreign Application Priority Data
Dec. 16, 2013 (JP) 2013-259135

(51) Int. Cl. H01H 19/54; H01H 36/00; B60R 16/023; G01D 5/12; H03K 17/972; B60K 37/06

(52) U.S. Cl. CPC H01H 19/54; H03K 17/972; B60K 37/06; B60R 16/0231; G01D 5/12; H01H 36/0073; H01H 2231/026

(57) ABSTRACT

The operation device includes ball sensors and a determination unit. Each of the ball sensors has a ball, whereof a portion is exposed from an opening provided in an operation surface, rotating in a first direction which is the direction of an operation performed on the operation surface, and a second direction which is a direction opposite to the first direction; a support rotatably supporting the ball, and a rotation sensor for detecting the rotation of the ball. The ball sensors are disposed so as to be arranged on the operation surface along the first direction. The determination unit determines the operations performed in the first direction and the second direction on the operation surface based on detection signals outputted from the rotation sensors of the of ball sensors.

### TECHNICAL FIELD

The present invention relates to an operation device for controlling an electric component, such as a turn signal and a windshield wiper, fitted on a vehicle.

### BACKGROUND ART

As a conventional technique, a stalk switch is known which is composed of a housing attached to a steering column etc. of an automobile and an operating lever protruding from the housing (see e.g. PTL 1).

The stalk switch is applied to a turn signal switch of automobile and is configured such that the operating lever is operable in two operation planes orthogonal to each other. The stalk switch is also configured such that a first actuator protruding from an end of the operating lever comes into contact with a cam plate arranged in the housing and having plural cam surfaces so as to provide detent for the operating lever.

### CITATION LIST

### Patent Literature

[PTL 1]

JP-A-2012-221583

### SUMMARY OF INVENTION

### Technical Problem

In the conventional stalk switch, it is difficult to reduce the operation load of the operating lever due to a structure for providing the detent, and a degree of freedom upon devising a new design is limited due to the composition of the housing and the operating lever.

It is an object of the invention to provide an operation device that allows reduction in operation burden, a novel design and an intuitive operation.

### Solution to Problem

According to an embodiment of the invention, an operation device comprises a plurality of rotating operation portions that are arranged in a line on an operation surface along a first direction as a direction of an operation performed on the operation surface and comprise a rotating member partially exposed from an opening provided in the operation surface and rotating in the first direction and a second direction opposite to the first direction, a support rotatably supporting the rotating member, and a detecting portion for detecting a rotation of the rotating member, and a determination unit that determines the operation performed in the first direction and the second direction on the operation surface based on a plurality of detection signals outputted from the detecting portions of the plurality of rotating operation portions.

### Advantageous Effects of Invention

According to an embodiment of the invention, an operation device can be provided that allows reduction in operation burden, a novel design and an intuitive operation.

### BRIEF DESCRIPTION OF DRAWINGS

FIG. 1A is an illustration diagram showing the inside of a vehicle on which an operation device in a first embodiment is fitted.

FIG. 1B is an enlarged view showing the vicinity of an operation surface of the operation device.

FIG. 2A is a cross sectional view taken along a line II(a)-II(a) and viewed in the direction of arrows concerning the operation device in the first embodiment.

FIG. 2B is a front view showing a ball sensor.

FIG. 2C is a block diagram showing the operation device.

FIG. 2D is a block diagram showing the vehicle.

FIG. 3A is an illustration diagram showing an example of operation of the operation device in the first embodiment.

FIG. 3B is a cross sectional view showing a main portion of the operation device before the operation is performed.

FIG. 3C is a cross sectional view showing the main portion of the operation device during the operation is performed.

FIG. 4A is an illustration diagram showing the inside of a vehicle on which an operation device in a second embodiment is fitted.

FIG. 4B is a table referenced by an operation device in a third embodiment.

FIG. 4C is a table referenced by the operation device in the third embodiment.

### DESCRIPTION OF EMBODIMENTS

### Summary of the Embodiments

Operation devices in embodiments are provided with a plurality of rotating operation portions that are arranged in a line on an operation surface along a first direction as a direction of an operation performed on the operation surface and include a rotating member partially exposed from an opening provided in the operation surface and rotating in the first direction and a second direction opposite to the first direction, a support rotatably supporting the rotating member and a detecting portion for detecting the rotation of the rotating member, and a determination unit that determines the operation performed in the first direction and the second direction on the operation surface based on a plurality of detection signals outputted from the detecting portions of the plurality of rotating operation portions.

The operation device allows reduction in operation burden, a novel design and an intuitive operation. In detail, the operation device can be operated by rotating the rotating members and thus is subjected to less operational load than a device operated using an operating lever. In addition, the operation device does not need to adapt the design using an operating lever and thus has a higher degree of freedom in designing than the device operated using an operating lever. Furthermore, since the operation device is operated in a one-dimensional direction and has rotating operation portions arranged along an operation direction, the operation method is simple and it is possible to operate intuitively.

### First Embodiment

(General Configuration of Operation Device 1)

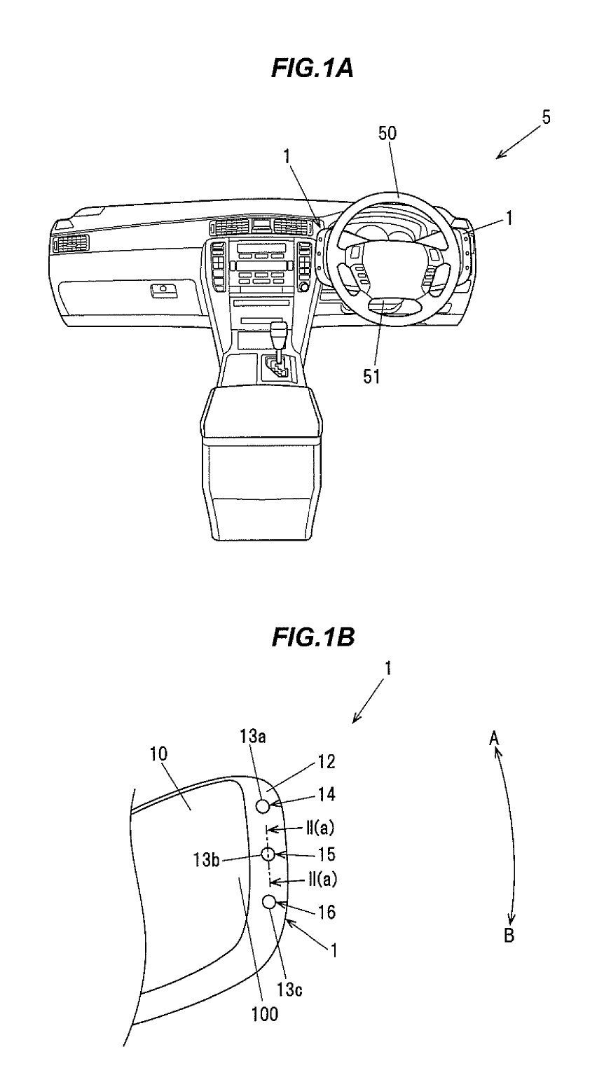

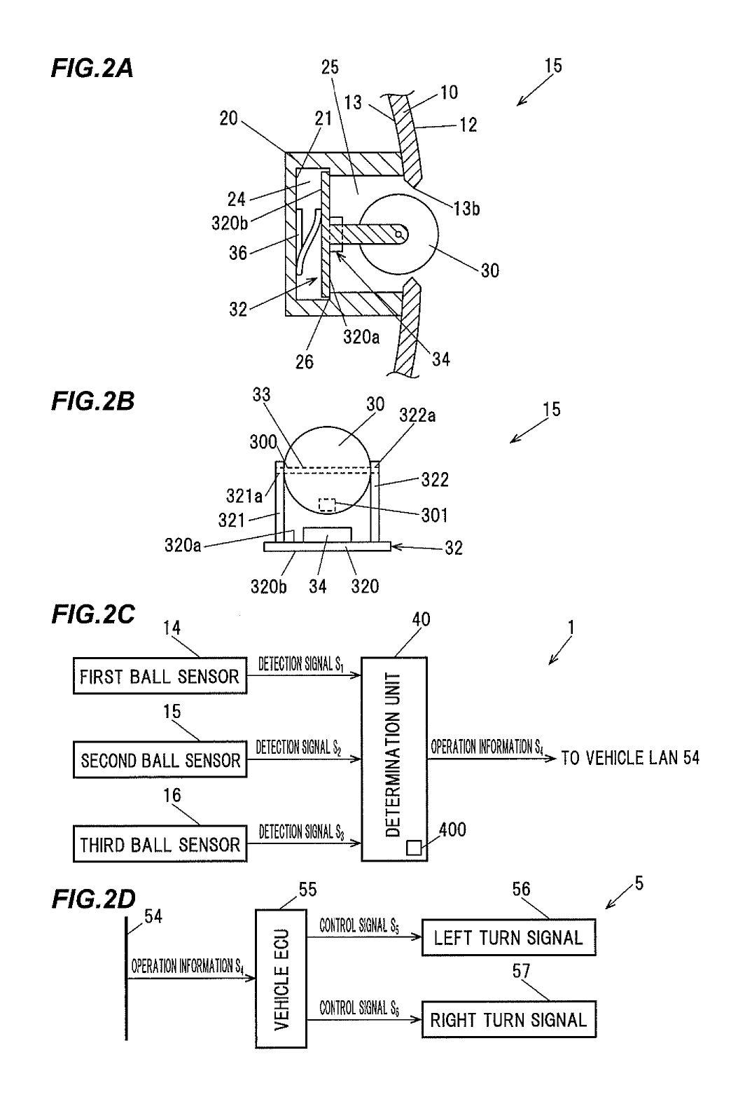

FIG. 1A is an illustration diagram showing the inside of a vehicle on which an operation device in the first embodiment is fitted and FIG. 1B is an enlarged view showing the vicinity of an operation surface of the operation device. FIG. 2A is a cross sectional view taken along a line II(a)-II(a) and viewed in the direction of arrows concerning the operation device in the first embodiment, FIG. 2B is a front view showing a ball sensor, FIG. 2C is a block diagram showing the operation device and FIG. 2D is a block diagram showing the vehicle. In each drawing of the embodiments described below, a scale ratio may be different from an actual ratio. In addition, in FIGS. 2C and 2D, main signals and information are indicated by arrows.

The operation device 1 is configured, e.g., so as to control the flashing of the turn signal of a vehicle 5 or to control the start and stop of a wiper device thereof. As an example, the operation device 1 for controlling the turn signal will be described in the first embodiment.

As shown in FIG. 1A, the operation device 1 is arranged to protrude from the right side surface of a steering column cover 51 arranged around a steering shaft which is a portion of a steering mechanism of the vehicle 5 and rotates with a steering wheel 50. Also, another operation device 1 for operating the wiper device is arranged to protrude from the left side surface of the steering column cover 51. The right and left directions mentioned above are directions as viewed by a driver as an operator.

As shown in FIGS. 1A and 1B, the operation device 1 is arranged close to the steering wheel 50 such that the operator can swipe an operation surface 12 with a finger stretched while gripping the steering wheel 50.

As shown in FIGS. 2A to 2C, the operation device 1 has plural ball sensors as rotating operation portions which are arranged in a line on the operation surface 12 along a first direction (the direction of arrow A) as a direction of an operation performed on the operation surface 12 and each have a ball 30 as a rotating member partially exposed from an opening provided on the operation surface 12 and rotating in the first direction and a second direction (the direction of arrow B) opposite to the first direction, a support 32 rotatably supporting the ball 30 and a rotation sensor 34 as a detecting portion for detecting the rotation of the ball 30, and a determination unit 40 which determines the operations performed in the first direction and the second direction on the operation surface 12 based on plural detection signals sent out from the rotation sensors 34 of the plural ball sensors.

The operation device 1 is provided with first to third ball sensors 14 to 16 as the plural ball sensors. The first to third ball sensors 14 to 16 have the same structure. Therefore, in the following description, the second ball sensor 15 will be mainly described. The number of the ball sensors is not limited to three and can be changed according to the specification of the operation device 1.

As shown in FIG. 2D, the vehicle 5 has a vehicle LAN (Local Area Network) 54, a vehicle ECU (Electronic Control Unit) 55, a left turn signal 56 and a right turn signal 57.

The operation device 1 is electromagnetically connected to the vehicle LAN 54. The vehicle ECU 55 outputs a control signal S₅ to a turn signal on the left side, i.e., the left turn signal 56 when determining, based on operation information S₄ acquired from the operation device 1, that a turn signal to be activated is the left turn signal 56. Alsowhile, the vehicle ECU 55 outputs a control signal S₆ to a turn signal on the right side, i.e., the right turn signal 57 when determining, based on the operation information S₄ acquired from the operation device 1, that a turn signal to be activated is the right turn signal 57.

Electromagnetic connection here is connection using at least one of connection by a conductive material, connection by light as a kind of electromagnetic wave and connection by radio wave as a kind of electromagnetic wave.

(Configuration of Main Body 10)

A main body 10 is formed in, e.g., a plate shape with a rounded edge 100, as shown in FIGS. 1A and 1B. An end face of the main body 10 is the operation surface 12 on which an opening 13a, an opening 13b and an opening 13c are formed in a line.

An attachment portion to be attached to a steering column covering a steering shaft is provided on the main body 10 at, e.g., an edge on the steering column cover 51 side.

(Configuration of the First to Third Ball Sensors 14 to 16)

As shown in FIG. 2A, the second ball sensor 15 is provided with a housing 20 in which the support 32 is arranged. The housing 20 is attached to a back surface 13 located on the reverse side of the operation surface 12.

The housing 20 is formed in, e.g., a box shape with open top. Inside the housing 20, a first housing portion 24 is formed on a bottom portion 21 side of the housing 20 and a second housing portion 25 is formed on the operation surface 12 side.

As shown in FIG. 2A, a step portion 22 providing a level difference is formed at a boundary between the first housing portion 24 and the second housing portion 25. The step portion 22 restricts a base portion 320 (described later) of the support 32 from moving toward the operation surface 12.

The ball 30 is, e.g., a spherical object. The ball 30 has an insertion hole 300 into which a shaft 33 is inserted. The ball 30 also has, e.g., a magnet 301 arranged thereinside. The ball 30 is, e.g., molded integrally with the magnet 301 using a resin.

The rotating member is not limited to the spherical ball 30 as long as it is a rotatable member such as circular disk.

The support 32 is arranged in the housing 20. As shown in FIG. 2B, the support 32 is composed of the base portion 320, and a first support rod 321 and a second support rod 322 which are provided along a normal direction of the base portion 320.

The base portion 320 is formed in, e.g., a plate shape and has a front surface 320a on which the rotation sensor 34 is arranged.

The first support rod 321 and the second support rod 322 are arranged at a distance so that the ball 30 is sandwiched therebetween. A through-hole 321a for rotatably supporting the ball 30 is formed on the first support rod 321. Likewise, a through-hole 322a for supporting the ball 30 is formed on the second support rod 322.

The ball 30 is rotatably supported on the support 32 by the shaft 33 inserted through the through-hole 321a of the first support rod 321, the insertion hole 300 of the ball 30 and the through-hole 322a of the second support rod 322.

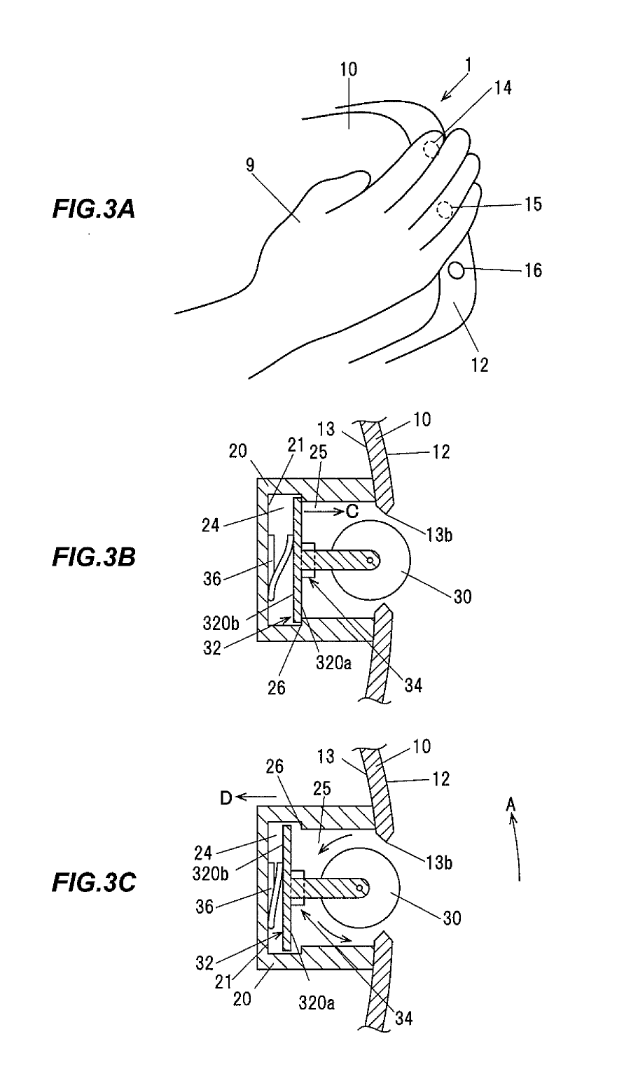

The second ball sensor 15 also has a flat spring 36 as an resilient member which is arranged between the housing 20 and the support 32, contracts in a direction of being pushed from the operation surface 12 side (a direction of arrow D shown in FIG. 3C (described later)) and accumulates an resilient force when the ball 30 is operated, and releases the accumulated resilient force in the direction toward the operation surface 12 (a direction of arrow C shown in FIG. 3B (described later)) after the completion of the operation.

In detail, the flat spring 36 is arranged between the bottom portion 21 of the housing 20 and a back surface 320b of the base portion 320 of the support 32. The flat spring 36 is formed by, e.g., folding a plate made of metal or resin.

The resilient member is not limited to the flat spring and may alternatively be, e.g., a coil spring which applies a force to the support 32 in a direction toward the operation surface 12 and allows the support 32 to be displaced in a direction of being pushed from the operation surface 12 side when the ball 30 is operated, or a member formed of, e.g., a rubber, etc., or an actuator which generates a force based on a supplied electric current.

The flat spring 36 applies an resilient force that displaces the base portion 320 of the support 32 toward the operation surface 12, as described above. However, movement of the support 32 is restricted by the step portion 22. Therefore, in the initial state in which an operation is not performed, the front surface 320a of the base portion 320 is in contact with the step portion 22 as shown in FIG. 2A. Meanwhile, the ball 30 is configured not to be in contact with the main body 10 in the initial state as well as in the operating state.

(Configuration of the Rotation Sensor 34)

The rotation sensor 34 is, e.g., a magnetic sensor which can detect rotation of the ball 30 without contact. This magnetic sensor is provided with, e.g., a magnetoresistive element and a Hall element, etc. The rotation sensor 34 only needs to be capable of detecting one dimensional rotation of the ball 30, and may be, e.g., a rotary encoder which can sense direction of rotation.

The rotation sensor 34 is configured to detect rotation of the ball 30 based on, e.g., variation in a magnetic field generated by the magnet 301 arranged in the ball 30.

The rotation sensor 34 of the first ball sensor 14 is configured to output a detection signal S₁ to the determination unit 40. The rotation sensor 34 of the second ball sensor 15 is configured to output a detection signal S₂ to the determination unit 40. The rotation sensor 34 of the third ball sensor 16 is configured to output a detection signal S₃ to the determination unit 40.

(Configuration of the Determination Unit 40)

The determination unit 40 is, e.g., a microcomputer composed of a CPU (Central Processing Unit) performing calculation and processing, etc., of the acquired data according to a stored program, a RAM (Random Access Memory) and a ROM (Read Only Memory) which are semiconductor memories. The ROM stores, e.g., a program for operation of the determination unit 40. The RAM is used as, e.g., a storage area for temporarily storing calculation results, etc. In addition, the determination unit 40 has a threshold 400 used for determining the operation.

The determination unit 40 is configured to generate operation information S₄ to activate the left turn signal 56 and to output the operation information S₄ to the vehicle ECU 55 when determining, based on the detection signals S₁ to S₃, that the first to third ball sensors 14 to 16 are rotated in the first direction (the direction of arrow A).

Also, the determination unit 40 is configured to generate operation information S₄ to activate the right turn signal 57 and to output the operation information S₄ to the vehicle ECU 55 when determining, based on the detection signals S₁ to S₃, that the first to third ball sensors 14 to 16 are rotated in the second direction (the direction of arrow B).

The first direction is a direction of an operation that an operator swipes the operation surface 12 from bottom up with the right hand. Also, the second direction is a direction of an operation that an operator swipes the operation surface 12 from top down with the right hand. “Up” here means a direction toward the ceiling of the vehicle 5 and “down” is a direction toward the floor of the vehicle 5.

Also, when not less than a predetermined number of the rotation sensors 34, among those in the plural ball sensors, detect rotation of the ball 30, the determination unit 40 determines that the operation is performed on the operation surface 12.

The predetermined number is set as the threshold 400. The determination unit 40 is configured to count the number of ball sensors which detected the rotation, then to compare the counted number with the threshold 400, and to determine whether or not an operation is performed.

In the first embodiment, when two or more of the first to third ball sensors 14 to 16 detect rotation of the ball 30, the determination unit 40 determines that an operation is performed.

When, for example, the direction of rotation of the ball 30 detected by one rotation sensor 34 is different that detected by other rotation sensors 34, the determination unit 40 determines that the rotation direction indicated by not less than the predetermined number of the rotation sensors 34 is the operation direction. Thus, when two rotation sensors 34 detect rotations in different directions, the determination unit 40 determines that it is not possible to determine the operation direction.

The operation of the operation device 1 in the first embodiment will be described below.

(Operation)

FIG. 3A is an illustration diagram showing an example of operation of the operation device in the first embodiment, FIG. 3B is a cross sectional view showing a main portion of the operation device before the operation is performed, and FIG. 3C is a cross sectional view showing the main portion of the operation device during the operation is performed. FIGS. 3B and 3C show the cross section taken along the line II(a)-II(a) in FIG. 1B and viewed in the direction of arrows.

An operation performed on the operation surface 12 from bottom up by a right hand 9 of an operator as shown in FIG. 3A to activate the left turn signal 56 will be described below.

When the operator performs an operation on the operation surface 12 from bottom up with the right hand 9, the ball 30 of the third ball sensor 16, that of the second ball sensor 15 and that of the first ball sensor 14 are rotated in this order.

At this time, each ball 30 rotates in the operation direction of the right hand 9, and at the same time, is pushed into the housing 20 toward the bottom portion 21 (in the direction of arrow D) from the initial state shown in FIG. 3B. The support 32 supporting the ball 30 moves together with the ball 30 in the direction of arrow D and compresses the flat spring 36. The rotation direction of the ball 30 is counterclockwise in the plane of FIG. 3C.

When the right hand 9 of the operator moves away from the ball 30, an accumulated resilient force of the flat spring 36 is released and displaces the support 32 in the direction of arrow C, i.e., toward the operation surface 12. The support 32 is displaced toward the operation surface 12 by the resilient force but is restricted from further moving by contact with the step portion 22 and stops at the initial position shown in FIG. 3B.

At this stage, based on this operation, the determination unit 40 acquires the detection signal S₁ from the first ball sensor 14, the detection signal S₂ from the second ball sensor 15 and the detection signal S₃ from the third ball sensor 16.

The determination unit 40 compares the threshold 400 with the number of ball sensors which detected rotation and, when the number of ball sensors which detected rotation is not less than the predetermined number, the determination unit 40 generates operation information S₄ based on the rotation direction and outputs the operation information S₄ to the vehicle ECU 55 via the vehicle LAN 54. This operation information S₄ is to activate the left turn signal 56.

Based on the acquired operation information S₄, the vehicle ECU 55 generates the control signal S₅ to activate the left turn signal 56 and outputs the control signal S₅ to the left turn signal 56. The left turn signal 56 flashes based on the acquired control signal S₅.

(Effects of the First Embodiment)

The operation device 1 in the first embodiment is subjected to less operational load, is excellent in design and can be operated intuitively.

In detail, since the operation device 1 can be operated by rotating the balls 30, the operational load is less than a device operated using an operating lever, and also, moderate cushioning properties are imparted by the flat spring 36. In addition, since the operation device 1 does not need to adapt the design using an operating lever, the degree of freedom in designing is higher than the device operated using an operating lever. Furthermore, since the operation device 1 is operated in a one-dimensional direction and has the balls 30 arranged along the operation direction, the operation method is simple and it is possible to operate intuitively.

### Second Embodiment

The second embodiment is different from other embodiments in the position of the operation device 1.

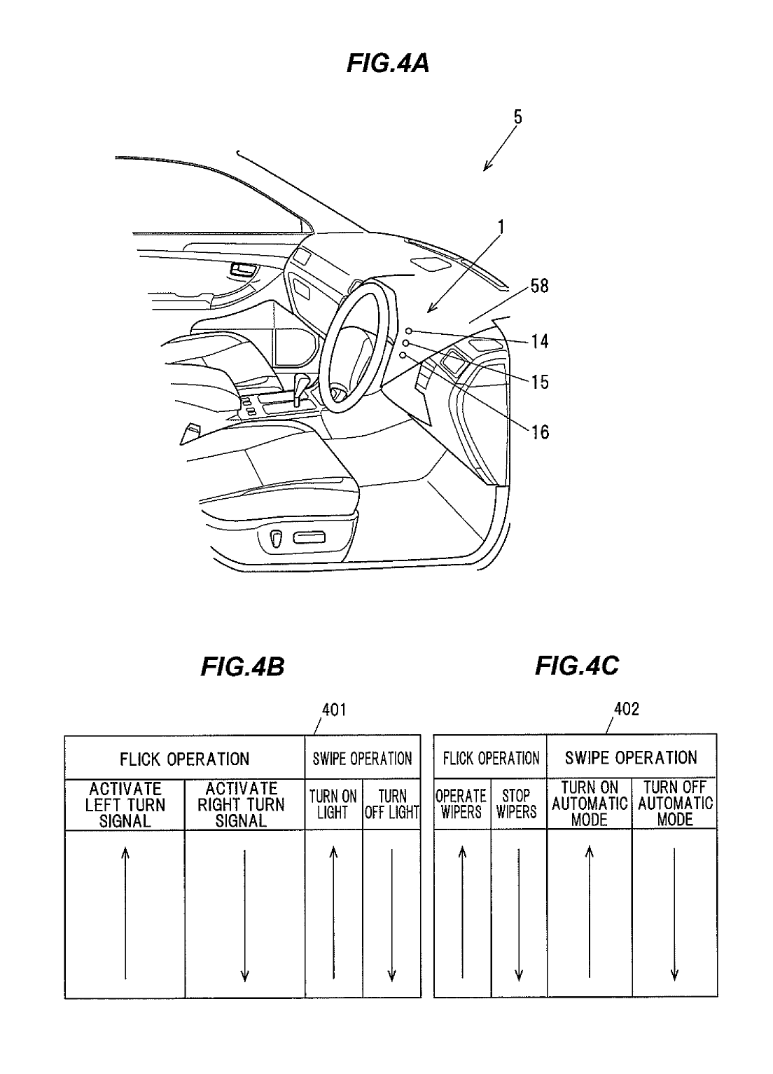

FIG. 4A is an illustration diagram showing the inside of a vehicle on which an operation device in the second embodiment is fitted. In the following description, portions having the same functions and structures as those in the first embodiment are denoted by the same reference numerals and the explanation thereof will be omitted.

As shown in FIG. 4A, the first to third ball sensors 14 to 16 of this operation device 1 are not provided to protrude from the steering column cover 51, but are arranged on a side portion 59 of an instrument panel cover 58 which is provided mainly to ensure visibility of instruments such as speedometer located in front of the operator. The operation device 1 is arranged on the right-hand side of the operator to operate turn signals.

The first to third ball sensors 14 to 16 are arranged in a line in a one-dimensional operation direction, in the same manner as the first embodiment.

Also, another operation device 1 capable of operating a wiper device, etc., is arranged in a line in a one-dimensional operation direction on a side portion of the instrument panel cover 58 on the left-hand side of the operator.

(Effects of the Second Embodiment)

Since the position to arrange the operation device 1 in the second embodiment is less limited than the device operated using an operating lever, the arrangement space and the shape of the object mounting the operation device 1 can be freely decided as long as it is within a range allowing an operation to be performed effortlessly while operating the steering wheel 50. Therefore, the degree of freedom in arrangement is improved and the degree of freedom in designing the periphery including the operation device 1 is also improved.

### Third Embodiment

The third embodiment is different from the above-described embodiments in that functions to be implemented are changed depending on the rotation direction and rotation speed of the ball 30.

FIGS. 4B and 4C are explanatory diagrams to explain tables referenced by an operation device in the third embodiment. Firstly, a table 401 for the operation device 1 arranged on the right-hand side of the operator will be described below.

The determination unit 40 of this operation device 1 has the table 401 shown in FIG. 4B. The table 401 includes information used to determine an operation based on the direction and speed of the operation performed on the operation surface 12 and to generate the operation information S₄ based on the determined operation. Such information is schematically shown in the table 401 of FIG. 4B.

The operations to be determined are, e.g., flick operation and swipe operation. The flick operation is, e.g., an operation to activate the turn signals. The determination unit 40 is configured to calculate the direction and speed of the operation based on the detection signals S₁ to S₃ for at least two cycles.

When the determination unit 40 determines based on the detection signals S₁ to S₃ and the table 401 that, e.g., a flick operation is performed from bottom up, the determination unit 40 generates and outputs the operation information S₄ to activate the left turn signal 56. On the other hand, when the determination unit 40 determines based on the detection signals S₁ to S₃ and the table 401 that, e.g., a flick operation is performed from top down, the determination unit 40 generates and outputs the operation information S₄ to activate the right turn signal 57.

Also, the swipe operation is an operation to rotate the balls 30 of the first to third ball sensors 14 to 16 slower than the flick operation. The swipe operation is, e.g., an operation on the operation surface 12 to turn on headlights, etc., of the vehicle 5 when performed bottom up and to turn off the lights when performed from top down.

When the determination unit 40 determines based on the detection signals S₁ to S₃ and the table 401 that, e.g., a swipe operation is performed from bottom up, the determination unit 40 generates and outputs the operation information S₄ to turn on the headlights, etc. On the other hand, when the determination unit 40 determines based on the detection signals S₁ to S₃ and the table 401 that, e.g., a swipe operation is performed from top down, the determination unit 40 generates and outputs the operation information S₄ to turn off the headlights, etc.

Next, a table 402 for the operation device 1 which is arranged on the left-hand side of the operator and is capable of operating a wiper device, etc., will be described.

The determination unit 40 of this operation device 1 has the table 402 shown in FIG. 4C. The table 402 includes information used to determine an operation based on the direction and speed of the operation performed on the operation surface 12 and to generate the operation information S₄ based on the determined operation. Such information is schematically shown in the table 402 of FIG. 4C.

The operations to be determined are, e.g., flick operation and swipe operation. The flick operation is, e.g., an operation to operate a wiper device.

When the determination unit 40 determines based on the detection signals S₁ to S₃ and the table 402 that, e.g., a flick operation is performed from bottom up, the determination unit 40 generates and outputs the operation information S₄ to operate the wiper device. On the other hand, when the determination unit 40 determines based on the detection signals S₁ to S₃ and the table 402 that, e.g., a flick operation is performed from top down, the determination unit 40 generates and outputs the operation information S₄ to stop the wiper device.

Also, the swipe operation is an operation on the operation surface 12 to turn on the automatic mode of the wiper device when performed bottom up and to turn off the automatic mode when performed from top down. The automatic mode is a mode to operate or stop the wiper device or to change the operating speed of the wiper device based on raindrop detection by a rain sensor mounted on the vehicle 5.

When the determination unit 40 determines based on the detection signals S₁ to S₃ and the table 402 that, e.g., a swipe operation is performed from bottom up, the determination unit 40 generates and outputs the operation information S₄ to turn on the automatic mode of the wiper device. On the other hand, when the determination unit 40 determines based on the detection signals S₁ to S₃ and the table 402 that, e.g., a swipe operation is performed from top down, the determination unit 40 generates and outputs the operation information S₄ to turn off the automatic mode of the wiper device.

(Effects of the Third Embodiment)

When using the operation device 1 in the third embodiment, plural functions of the connected electronic device can be implemented by changing in the operation speed.

The operation device 1 in at least one of the above-described embodiments allows for reduction in operation burden, a novel design and an intuitive operation.

Although some embodiments and modifications of the invention have been described above, the embodiments and modifications are merely an example and the invention according to claims is not to be limited thereto. These new embodiments and modifications may be implemented in various other forms, and various omissions, substitutions and changes, etc., can be made without departing from the gist of the invention. In addition, all combinations of the features described in the embodiments and modifications are not necessary to solve the problem of the invention. Further, these embodiments and modifications are included within the scope and gist of the invention and also within the invention described in the claims and the equivalency thereof.

### INDUSTRIAL APPLICABILITY

The invention is applicable to an operation device for controlling an electric component, such as a turn signal and a windshield wiper, fitted on a vehicle.

### REFERENCE SIGNS LIST

1: OPERATION DEVICE

5: VEHICLE

9: RIGHT HAND

10: MAIN BODY

12: OPERATION SURFACE

13: BACK SURFACE

13a to 13c: OPENING

14 TO 16: FIRST TO THIRD BALL SENSORS

20: HOUSING

21: BOTTOM PORTION

22: STEP PORTION

24: FIRST HOUSING PORTION

25: SECOND HOUSING PORTION

30: BALL

32: SUPPORT

33: SHAFT

34: ROTATION SENSOR

36: FLAT SPRING

40: DETERMINATION UNIT

50: STEERING WHEEL

51: STEERING COLUMN COVER

55: VEHICLE ECU

56: LEFT TURN SIGNAL

57: RIGHT TURN SIGNAL

58: INSTRUMENT PANEL COVER

59: SIDE PORTION

100: EDGE

300: INSERTION HOLE

301: MAGNET

302: BASE PORTION

320a: FRONT SURFACE

320b: BACK SURFACE

321: FIRST SUPPORT ROD

321a: THROUGH-HOLE

322: SECOND SUPPORT ROD

322a: THROUGH-HOLE

400: THRESHOLD

401: TABLE

402: TABLE

1. An operation device, comprising:
a plurality of rotating operation portions that are arranged in a line on an operation surface along a first direction as a direction of an operation performed on the operation surface and comprise a rotating member partially exposed from an opening provided in the operation surface and rotating in the first direction and a second direction opposite to the first direction, a support rotatably supporting the rotating member, and a detecting portion for detecting a rotation of the rotating member; and
a determination unit that determines the operation performed in the first direction and the second direction on the operation surface based on a plurality of detection signals outputted from the detecting portions of the plurality of rotating operation portions,
wherein the determination unit determines that the operation is performed on the operation surface when not less than a predetermined number of the detecting portions, among the plurality of detecting portions corresponding to the plurality of rotating operation portions, detect rotation of the rotating member.

2. The operation device according to claim 1, wherein the rotating operation portion comprises an resilient member that is arranged between the support and a housing accommodating the support therein, contracts in a direction of the rotating member being pushed into from the operation surface and accumulates an resilient force when the rotating member is operated, and releases the accumulated resilient force in a direction toward the operation surface after the operation is completed.

3. (canceled)

4. The operation device according to claim 1, wherein the operation surface is formed on a main body protruding from a vehicle steering column.

5. The operation device according to claim 1, wherein the operation surface is formed on a side surface of a cover that covers instrument provided near the vehicle steering wheel.

6. The operation device according to claim 1, wherein the rotating member comprises a spherical object having a magnet therein, and the detecting portion comprises a magnetic sensor.

7. The operation device according to claim 1, wherein the first direction comprises a direction from a floor to a ceiling in a vehicle.

8. The operation device according to claim 1, wherein different functions are implemented by the rotation of the rotating member in the first direction and that in the second direction.

9. The operation device according to claim 1, wherein different functions are implemented by changing a rotation speed of the rotating member.
